(19) United States
(12) Patent Application Publication
(10) Pub. No.: US 2014/0041585 A1
(43) Pub. Date: Feb. 13, 2014

(54) EXHAUST GAS PROCESSING CONDUIT, MANUFACTURING APPARATUS AND GAS FLOW GUIDING METHOD THEREOF

(71) Applicants: Chin-Ming Hsu, Tainan City (TW); Guan-Ping Huang, Yunlin County (TW)

(72) Inventors: Chin-Ming Hsu, Tainan City (TW); Guan-Ping Huang, Yunlin County (TW)

(73) Assignee: UNITED MICROELECTRONICS CORP., HSINCHU (TW)

(21) Appl. No.: 13/571,475

(22) Filed: Aug. 10, 2012

(51) Int. Cl. F03B 11/00; C23C 16/44

(52) U.S. Cl. 118/715; 137/602; 137/1

(57) ABSTRACT

An exhaust gas processing conduit includes a main pipe and a purge pipe. The main pipe has a first sidewall and a connecting port formed on the first sidewall. The purge pipe has one end connected to the first sidewall via the connecting port. The purge pipe has a second sidewall in contact with the first sidewall at an oblique angle. A gas provided by the purge pipe is injected along the first sidewall and into the main pipe so as to guide the gas flowing along a spiral route at the oblique angle. In addition, a manufacturing apparatus and a gas flow guiding method thereof are also disclosed in the invention.

### BACKGROUND OF THE INVENTION

1. Field of the Invention

The invention relates in general to semiconductor process and apparatus, and more particularly to an exhaust gas processing conduit, a purge pipe and a gas flow guiding method thereof.

2. Description of the Related Art

When semiconductor devices are fabricated, the manufacturing process mainly includes diffusion, deposition, etching, and cleaning etc.; especially the diffusion and deposition processes involve the use of a great deal of reactive gases, such as SiH₄, Si₂H₂CL₂ and so on. Some gases are reacted on the wafer, but a large portion of gases that did not react become an exhaust gas. The exhaust gas cannot be vented directly, and needs to be transferred by the pipes and processed by an exhaust gas processing device, such as an exhaust gas scrubber. However, the exhaust gas of a high temperature, while passing through the pipes, may cool down and deposit cooled particles of the exhaust gas on the sidewall of the transmission pipes to cause accumulation and block in the pipes. Thus, the exhaust gas generated during the manufacturing process cannot be vented outside smoothly.

A similar problem of deposition of the exhaust gas particles also occurs in the reactive chamber of the manufacturing apparatus. In addition, an uneven distribution of gas in the reactive chamber would make the growth of reactant uneven. Thus, these problems would result in the semiconductor manufacturing process with a reduced yield rate.

### SUMMARY OF THE INVENTION

It is therefore directed to an exhaust gas processing conduit and a gas flow guiding method thereof to resolve the problem of deposition of exhaust gas particles.

It is therefore directed to a manufacturing apparatus and a gas flow guiding method thereof to guide and distribute the gas flow in the reactive chamber.

According to an embodiment, an exhaust gas processing conduit is provided, which includes a main pipe and a purge pipe. The main pipe has a first sidewall and a connecting port formed on the first sidewall. The purge pipe has one end connected to the first sidewall via the connecting port. The purge pipe has a second sidewall in contact with the first sidewall at an oblique angle. A gas provided by the purge pipe is injected along the first sidewall and into the main pipe so as to guide the gas flowing along a spiral route at the oblique angle.

According to an embodiment, a gas flow guiding method is provided with the following steps. A gas provided by a purge pipe is injected into a main pipe. The purge pipe is in contact with the main pipe at an oblique angle. The gas is injected along a sidewall of the main pipe, and the gas is guided to flow along a spiral route at the oblique angle.

According to another embodiment, a manufacturing apparatus is provided, which includes a reactive chamber, a gas transmission system and a purge system. The reactive chamber has a connecting port. The gas transmission system includes at least one pipe, and one end of which is connected to the reactive chamber via the connecting port. The pipe is in contact with a sidewall of the reactive chamber at an oblique angle. A gas provided by the pipe is injected along the sidewall of the reactive chamber and into the reactive chamber so as to guide the gas flowing along a periphery route at the oblique angle. The purge system is connected to the reactive chamber for venting the gas not to be reacted.

According to another embodiment, a gas flow guiding method is provided with the following steps. A gas provided by at least one pipe is injected into a reactive chamber. The pipe is in contact with a sidewall of the reactive chamber at an oblique angle. The gas is injected along the sidewall of the reactive chamber, and the gas is guided to flow along a periphery route at the oblique angle.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIGS. 1 and 2 are schematic views showing two additional purge pipes.

FIG. 3 is a schematic side view showing an exhaust gas processing conduit according to an embodiment of the invention.

FIG. 4 is a schematic top view showing an exhaust gas processing conduit according to an embodiment of the invention.

FIG. 5 is a cross-sectional view showing the main pipe and the purge pipe near the connecting port.

FIG. 6 is a schematic view showing a manufacturing apparatus and a gas flow guiding method thereof according to an embodiment of the invention.

### DETAILED DESCRIPTION OF THE INVENTION

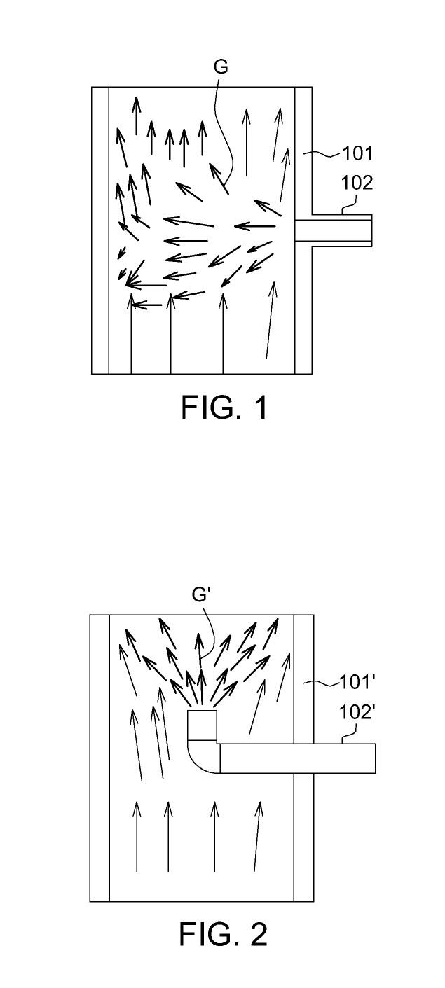

According to an exhaust gas processing conduit, a manufacturing apparatus, and a gas flow guiding method thereof in the present embodiments, a purge gas is utilized to dilute the concentration of the exhaust gas and maintain the temperature of the exhaust gas in the main pipe, so as to reduce the deposition of gas particles. Referring to FIGS. 1 and 2, the schematic views of two additional purge pipes are shown respectively. As shown in FIG. 1, the purge pipe 102 is vertical to the main pipe 101 and is fixedly connected to the sidewall of the main pipe 101. However, the purge gas G injected from a connecting port at a high speed causes a turbulent gas flow and blocks the exhaust gas to flow forward. In addition, as shown in FIG. 2, the purge pipe 102′ is an elbow tube, which penetrates into the main pipe 101′, and the purge gas G′ is injected along the direction of the gas flow to prevent the gas flow from being turbulent, but the gas flow blocked by the purge pipe 102′ causes the particles of the gas flow deposited on the purge pipe 102′, so that the problem of deposition of exhaust gas particles can not be resolved effectively.

A number of embodiments are disclosed below for exemplary purpose, not for limiting the scope of protection of the invention.

### First Embodiment

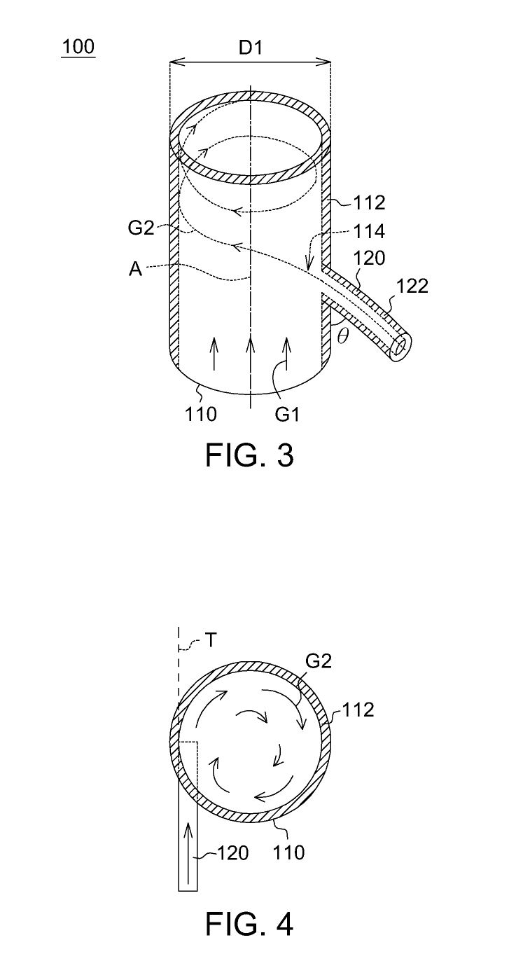

Referring to FIGS. 3 and 4, a schematic side view and a top view of an exhaust gas processing conduit according to an embodiment of the invention are shown. The exhaust gas processing conduit 100 includes a main pipe 110 and a purge pipe 120. In the main pipe 110, an exhaust gas G1, for example, may flow along the direction as indicated by arrows in FIG. 3, and include unreacted gases and byproducts derived from the reaction in the process. After pressurized by a vacuum pump (not shown), the exhaust gas G1 is transmitted through the main pipe 110 and then collected for performing cleaning process by an exhaust gas processing device.

In addition, the purge pipe 120 provides a purge gas G2 flowing along the direction as illustrated by a spiral arrow in FIG. 3, for example. The purge gas G2 can be a hot inert gas (such as a nitrogen gas at 130° C.) or a dilution gas. The purge gas G2 meets the exhaust gas G1 in the main pipe 110 near a connecting port 114. In the present embodiment, the purge gas G2 is not injected toward the center of the main pipe 110 in order to prevent turbulent flow or block the gas flowing forward. Instead, the purge gas G2 is injected close to the sidewall 112 and along a clockwise or counterclockwise spiral route, as shown in the FIGS. 3 and 4.

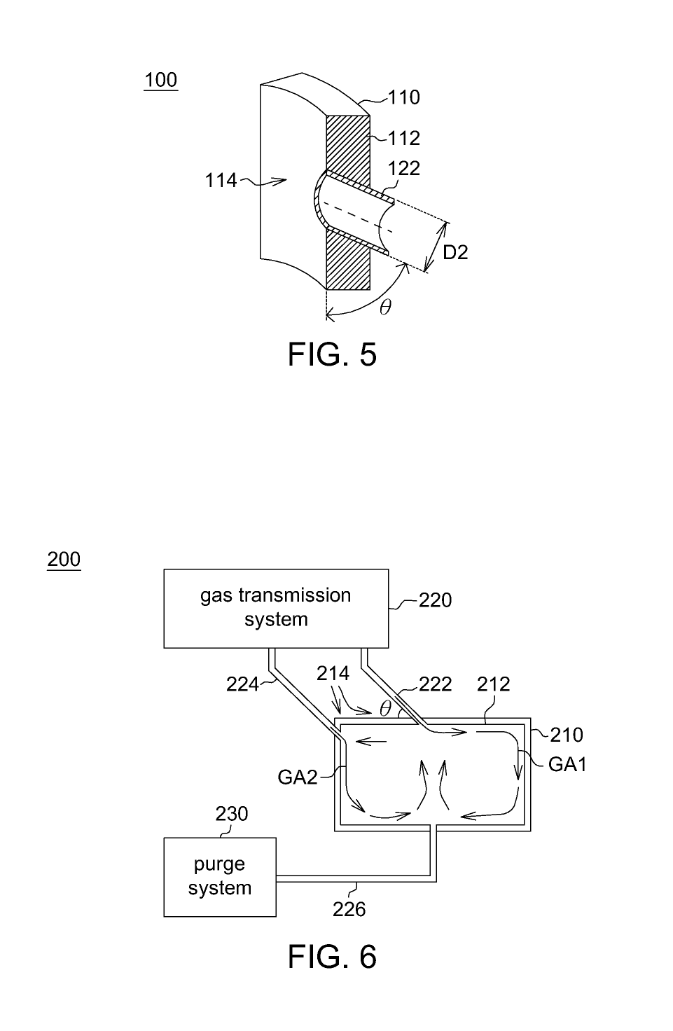

Referring to FIG. 5, a cross-sectional view of the main pipe 110 and the purge pipe 120 near the connecting port 114 is shown. In an embodiment, the main pipe 110 has a first sidewall 112 and the connecting port 114 formed on the first sidewall 112. The diameter D2 of the connecting port 114 is the same as that of the purge pipe 120. One end of the purge pipe 120 is inserted into the first sidewall 112 via the connecting port 114 so that the purge pipe 120 and the main pipe 110 are connected to each other. The purge pipe 120 has a second sidewall 122, which is in contact with the first sidewall 112 at an oblique angle 8. That is, the purge pipe 120 is connected to the connecting port 114, which is formed on the tangent direction T of the contour of the first sidewall 112, and the purge gas G2 is injected into the main pipe 110 at an angle smaller than 90 degree with respect to the axial A of the main pipe 110 so that the purge gas G2 is injected into the main pipe 110 along the contour of the first sidewall 112 and the gas G2 is guided to flow along a spiral route at the oblique angle θ, as shown in the FIG. 3.

In an embodiment, the purge gas G2 is an eddy current, and the flow speed of the purge gas G2 is greater than that of the exhaust gas G1 flowing axially to increase the purge effect, for example. In addition, the diameter D1 of the main pipe 110 is, for example, about 5 to 10 times of the diameter D2 of the purge pipe 120 so that the purge gas G2 can be injected into the main pipe 110 along the contour of the first sidewall 112 as close as possible. Moreover, the injecting angle (i.e., θ) of the purge gas G2 is, for example, between 15-75 degrees. The angle illustrated in the drawing is exemplified as 45 degrees, but the embodiment is not limited thereto.

### Second Embodiment

Referring to FIG. 6, a schematic view of a manufacturing apparatus 200 according to an embodiment of the invention is shown. Taken the apparatus required for deposition process for example, the process includes chemical vapor deposition and physical vapor deposition. In order to achieve vapor deposition, the gas transmission system 220 is required to inject the reactive gases to the top of the object to be deposited (such as a wafer) in the reactive chamber 210 to make the depositions cover the surface of the object, regardless of the reactive chamber 210 being at the atmospheric pressure, low pressure or being plasma enhanced. The unreacted gas and the byproduct are then vented through the purge system 230 (such as a pump). In addition, taken the thermal oxidation process, the thermal diffusion process and the rapid thermal process for example, some gases are injected into the apparatus which may include a horizontal furnace, a vertical furnace and a rapid thermal processing (RTP) reactive chamber so as to perform a reaction of growth of oxide. In this example, the gases for the reaction may be oxygen gas and applicable dilution gas (such as inert gas or nitrogen gas), or oxygen gas and reduction gas (such as hydrogen gas). After that, the unreacted gas and the byproduct are vented to outside through the purge system 230 (such as a pump).

Since the problem of deposition of exhaust gas particles also occurs on the sidewall 212 of the reactive chamber 210, the present embodiment can further employ an approach in the similar way as illustrated in the first embodiment. For example, the gas is injected into the reactive chamber 210 at an angle smaller than 90 degrees so that the gas enters the reactive chamber 210 along the sidewall 212 to guide the gas flowing along a peripheral route at first, and then the gas is distributed evenly in the reactive chamber 210 through the diffusion.

Referring to the FIG. 6, the gas transmission system 220 includes a first pipe 222 and a second pipe 224 for transmitting a reactive gas, a dilution gas, a reduction gas, other functional gas or the combination thereof. The first pipe 222 and the second pipe 224 are connected to the reactive chamber 210 via the connecting ports 214, so that the first pipe 222 and the second pipe 224 are in contact with the reactive chamber 210 at an oblique angle θ, respectively. In an embodiment, a first gas GA1 flows along a first direction, and a second gas GA2 flows along a second direction opposite to the first direction to generate an eddy current for the gas. Therefore, the two gases GA1 and GA2 are not injected directly into the center of the reactive chamber 210. Instead, the gases GA1 and GA2 are injected close to the sidewall 212 so as to guide the gases GA1 and GA2 flowing along a peripheral route and then the gases GA1 and GA2 are distributed evenly through the diffusion. After that, the unreacted gas and the byproduct derived from the reaction are vented to the purge system 230 through a third pipe 226.

In an embodiment, the reactive chamber 210 is shaped like a square, a circle, an ellipse or a round etc. The injecting angle (i.e., θ) of the gas is, for example, between 15-75 degrees. The angle illustrated in the drawing is exemplified as 45 degrees, but the invention is not limited thereto. In addition, the reactive gas can be oxygen, SiH₄, Si₂H₂CL₂ or fluoride- containing gas, for example. The dilution gas (or carrier gas) can be nitrogen or argon etc., and the reduction gas can be hydrogen, for example.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An exhaust gas processing conduit, comprising:
a main pipe having a first sidewall and a connecting port formed on the first sidewall; and
a purge pipe having one end connected to the first sidewall via the connecting port, wherein the purge pipe has a second sidewall in contact with the first sidewall at an oblique angle, the purge pipe injects a gas along the first sidewall and into the main pipe so as to guide the gas flowing along a spiral route at the oblique angle.

2. The exhaust gas processing conduit according to claim 1, wherein the gas includes an eddy current in the main pipe.

3. The exhaust gas processing conduit according to claim 1, wherein the oblique angle is between 15-75 degrees.

4. The exhaust gas processing conduit according to claim 1, wherein the connecting port is disposed on a tangent direction of a contour of the first sidewall.

5. The exhaust gas processing conduit according to claim 1, wherein the gas includes an inert gas.

6. A gas flow guiding method, comprising:
providing a gas from a purge pipe and injecting the gas into a main pipe, wherein the purge pipe is in contact with the main pipe at an oblique angle;
injecting the gas along a sidewall of the main pipe; and
guiding the gas to flow along a spiral route at the oblique angle.

7. The method according to claim 6, wherein the gas is an eddy current in the main pipe.

8. The method according to claim 6, wherein the oblique angle is between 15-75 degrees.

9. The method according to claim 6, wherein the connecting port is disposed on a tangent direction of a contour of the first sidewall.

10. The method according to claim 6, wherein the gas is an inert gas.

11. A manufacturing apparatus, comprising:
a reactive chamber having a connecting port;
a gas transmission system including at least one pipe, one end of the pipe being connected to the reactive chamber via the connecting port, wherein the pipe is in contact with a sidewall of the reactive chamber at an oblique angle, and a gas provided by the pipe is injected along the sidewall of the reactive chamber and into the reactive chamber so as to guide the gas flowing along a periphery route at the oblique angle; and
a purge system connected to the reactive chamber for venting the gas not to be reacted.

12. The manufacturing apparatus according to claim 11, wherein the gas is an eddy current in the reactive chamber.

13. The manufacturing apparatus according to claim 11, wherein the oblique angle is between 15-75 degrees.

14. The manufacturing apparatus according to claim 11, wherein the reactive chamber comprises a vapor deposition reactive chamber, a thermal reactive chamber or a furnace.

15. The manufacturing apparatus according to claim 11, wherein the gas comprises a reactive gas, a dilution gas, a reduction gas, an inert gas or a combination thereof.

16. A gas flow guiding method, comprising:
providing a gas from at least one pipe and injecting the gas into a reactive chamber, wherein the pipe is in contact with a sidewall of the reactive chamber at an oblique angle;
injecting the gas along the sidewall of the reactive chamber; and
guiding the gas to flow along a periphery route at the oblique angle.

17. The method according to claim 16, wherein the gas is an eddy current in the reactive chamber.

18. The method according to claim 16, wherein the oblique angle is between 15-75 degrees.

19. The method according to claim 16, wherein the reactive chamber comprises a vapor deposition reactive chamber, a thermal reactive chamber or a furnace.

20. The method according to claim 16, wherein the gas comprises a reactive gas, a dilution gas, a reduction gas, an inert gas or a combination thereof.
